(19) United States
(12) Patent Application Publication
(10) Pub. No.: US 2010/0046765 A1
(43) Pub. Date: Feb. 25, 2010

(54) SYSTEM FOR PROCESSING AUDIO DATA

(75) Inventors: Werner Paulus Josephus De Bruijn, Eindhoven (NL); Daniel Willem Elisabeth Schobben, Eindhoven (NL)

Correspondence Address: PHILIPS INTELLECTUAL PROPERTY & STANDARDS, P.O. BOX 3001, BRIARCLIFF MANOR, NY, 10510, US

(73) Assignee: KONINKLIJKE PHILIPS ELECTRONICS N.V., EINDHOVEN (NL)

(21) Appl. No.: 12/519,531

(22) PCT Filed: Dec. 14, 2007
(86) PCT No.: PCT/IB07/55106

§ 371 Date: Jun. 17, 2009

(30) Foreign Application Priority Data
Dec. 21, 2006 (EP) 06126753.0

(51) Int. Cl. H04R 29/00; H03G 3/00

(52) U.S. Cl. 381/58; 381/104

(57) ABSTRACT

A device (110) for processing audio data (106) for a multi channel audio playback system (100), comprises an identification unit (115), an extraction unit (120), and an averaging unit (125). The identification unit identifies segments of the audio data (106) related to a selected one of the channels (101 to 103) and belonging to a reference audio class. The extraction unit (120) extracts an audio property of the identified segments. The averaging unit (125) estimates an average value over a predetermined time period of the audio property of the channel (101) based on the extracted audio property of the identified segments.

### FIELD OF THE INVENTION

The invention relates to a device for processing audio data.

Beyond this, the invention relates to a multi channel audio playback apparatus.

The invention further relates to a method of processing audio data.

Moreover, the invention relates to a program element.

Further, the invention relates to a computer-readable medium.

### BACKGROUND OF THE INVENTION

Audio playback devices become more and more important. Particularly, an increasing number of users buy audio players comprising multiple loudspeakers and other entertainment equipment.

A common source of annoyance when watching TV is the fact that the loudness of different channels can vary significantly. This is especially apparent and annoying when switching (“zapping”) between channels. A similar effect occurs when switching between different sound sources connected to the same home entertainment system, such as a DVD player, VCR, TV, hard disk recorder or radio tuner, or when switching between channels on a radio or Internet radio.

Conventionally, such a problem may be addressed in enabling users to manually set and store a level offset for each individual channel. This, however, is a very user-unfriendly, cumbersome process, and as a consequence this feature is hardly ever used by the consumer. Other solutions try to maintain a constant loudness by using some sort of compressor-like circuit/processing. This, however, has several disadvantages. First of all, compression often results in audible pumping artifacts, caused by the continuous changing of the gain. Second, it is not desirable that all different types of content are reproduced at the same loudness, since this removes all the dynamics of the program material.

US 2004/0044525 discloses obtaining an indication of the loudness of an audio signal containing speech and other types of audio material by classifying segments of audio information as either speech or non-speech. The loudness of the speech segments is estimated and this estimate is used to derive the indication of loudness. The indication of loudness may be used to control audio signal levels so that variations in loudness of speech between different programs is reduced.

However, the quality of the equilibration of loudness differences according to US 2004/0044525 may be still insufficient.

### OBJECT AND SUMMARY OF THE INVENTION

It is an object of the invention to enable a user-friendly audio property control.

In order to achieve the object defined above, a device for processing audio data, a method of processing audio data, a program element, and a computer-readable medium according to the independent claims are provided. The dependent claims define advantageous embodiments.

According to an exemplary embodiment of the invention, a device for processing audio data for a multi channel audio playback system is provided, the device comprising an identification unit adapted for identifying segments of the audio data related to a selected one of the channels and belonging to a reference audio class, an extraction unit adapted for extracting an audio property of the identified segments, and an averaging unit adapted for estimating a long-term average of the audio property of the channel based on the extracted audio property of the identified segments.

According to another exemplary embodiment of the invention, a multi channel audio playback apparatus is provided comprising a device for processing audio data having the above-mentioned features.

According to still another exemplary embodiment of the invention, a method of processing audio data for a multi channel audio system is provided, the method comprising identifying segments of the audio data related to a selected one of the channels and belonging to a reference audio class, extracting an audio property of the identified segments, and estimating a long-term average of the audio property of the channel based on the extracted audio property of the identified segments.

According to still another exemplary embodiment of the invention, a program element (e.g. an item of a software library, in source code or in executable code) is provided, which, when being executed by a processor, is adapted to control or carry out a method of processing audio data having the above mentioned features.

According to yet another exemplary embodiment of the invention, a computer-readable medium (e.g. a CD, a DVD, a USB stick, a floppy disk or a hard disk) is provided, in which a computer program is stored which, when being executed by a processor, is adapted to control or carry out a method of processing audio data having the above mentioned features.

The audio data processing according to embodiments of the invention can be realized by a computer program, that is by software, or by using one or more special electronic optimization circuits, that is in hardware, or in hybrid form, that is by means of software components and hardware components.

The term “multi channel audio playback system” may particularly denote any audio reproduction system (which may be realized as an apparatus or a procedure), which allows a user to listen to the content of one of a plurality of different audio channels. An example is a television device in which the user may select among multiple broadcasting channels each providing reproducible audio content. Also in radio devices, one of different channels may be selected. Web-based systems in which Internet radio streams may be reproduced may offer a plurality of channels as well. Furthermore, a stereo system may allow to reproduce audio content from different media, such as a CD, a DVD, a radio and a cassette.

The term “segments of the audio data” may denote portions of the audio data such as audio frames or audio intervals having a common (audio) property. The sequence of audio segments forms the complete audio stream.

The term “reference audio class” may denote a specific class of audio content defined by one or more audio property criteria. Such a classification may particularly include the distinction between speech and non-speech segments. Such a classification may also include the distinction between different music genres such as classic, pop, jazz, etc. A procedure of classification is disclosed for instance in R. M. Aarts and Robert Toonen Dekkers, “A real-time speech-music discriminator”, J. Audio Eng. Soc., 47(9):720-725, September 1999.

The term “audio property” may denote a characteristic of the audio content which has an influence of the perception of the reproduced audio content by a human listener. Examples are loudness, a frequency distribution, etc.

The term “long-term average” denotes that the average value of the audio property is detected for a specific channel over a predetermined period of time. The period time may be sleeted sufficiently long so that a sufficient statistical reliability of the average audio property value for this channel may be obtained. This may include measuring the audio property in a plurality of intervals during which a user has switched on the specific channel. A sufficiently long time may be in the order of magnitude of minutes (for instance 1 minute or 30 minutes), and may range to the order of magnitude of days or even months, for example, a channel is watched by a user continuously for one day, or a channel is selected by a user with interruption for several days or even longer.

According to an exemplary embodiment of the invention, audio speech segments are identified in an audio stream of a channel to which a user has switched. Speech segments may be a meaningful source of content for deriving an average loudness value. Therefore, taking an average of the loudness over different speech periods for a specific channel may serve as a measure for a realistic loudness of the audio content reproduced by a specific channel. This (arithmetic or median) average value of the loudness or any other audio related property may be determined over a sufficiently long term. For instance, each time a user switches to a channel, a measurement may be carried out and an actual average value may be substituted by an updated average value. This average value which may be typical for a channel and which may significantly differ between different channels may then be compared to a reference value (which can be user-defined, predetermined or generated by an average of the average values for the different channels), and a gain correction may be performed on the basis of this comparison to attenuate or amplify a loudness of a specific channel, thereby providing an amplitude equilibration among various channels.

One exemplary aspect of the invention is the fact that upon switching from the current channel to another one, the current long-term average may be stored, which may be recalled the next time the user switches back to the channel, after which the averaging process continues, starting from this stored value. This is advantageous, since this may ensure that after some time it is possible to reach a stable state where the stored values are really representative of the average speech loudness of each channel. The conventional system of US 2004/0044525 A1 does not allow to obtain these advantages.

From production to broadcasting, the lack of enforced stringent loudness regulations within the television network results in an inconsistent loudness level between channels/programs. Using an objective loudness measure of the speech content to normalize the incoming broadcast audio, a simulative real time system may be provided to suppress the perceived annoyances associated with the inconsistent inter-channel loudness level. According to an exemplary embodiment of the invention, a system for equilibrating inter-channel loudness differences may be provided. Therefore, a system capable of reproducing the same subjective loudness level for all programs/sources may be provided.

According to an exemplary embodiment of the invention, an automatic inter-channel loudness equalization for television and home entertainment systems may be provided. Such an automated inter-channel loudness equalization may be obtained by an audio analysis, segment-wise to identify a reference type content, for instance speech, as a reference for loudness and measurement of the loudness. Furthermore, it is possible to compute a long-term average of loudness for this reference content, for each channel. Then, it is possible to equalize the loudness for the reference content type to the reference loudness level, across the channels.

According to an exemplary embodiment of the invention, a device for processing audio signals of at least one audio channel is provided. The device may comprise a classifier adapted to classify segments of the audio signals as being either specific type of content or not (for instance speech segments or non-speech segments). Furthermore, means for examining the specific type of content to derive a loudness information of the specific type of content may be provided. Averaging means may be adapted to perform a long-term average of the loudness information.

The averaging means may be adapted for performing a cumulative average process of the loudness information. The cumulative average process may be resumed from a previously stored average value of the loudness information of the audio channel when the channel is activated. According to an exemplary embodiment, other signal characteristics than loudness may be evaluated (specific type of information), for example a frequency spectrum (for automated equalization of the spectrum of all channels), a dynamic range, and/or spatial properties (for instance a stereo spread).

In a further embodiment, when an audio channel is activated, prior to starting the sound output for this channel, a stored average loudness value of the channel may be recalled from a memory and compared to a reference loudness value, which reference loudness value is the same for all channels.

In a further embodiment, a gain correction may be applied to the audio signal of the channel, which compensates the differences between the recalled average loudness value of the channel and the reference value.

Consequently, the same type of content, for instance speech dialog, may simultaneously be reproduced with the same loudness across all channels, since this will result in an overall loudness alignment of all channels, while the dynamics of the original audio signal and the different types of content are preserved.

Exemplary fields of application of exemplary embodiments of the invention are television devices, home entertainment systems, (car/mobile) radio devices, etc.

According to an exemplary embodiment of the invention, an automatic inter-channel loudness equalization for television and home entertainment systems may be provided. This may prevent the common source of annoyance when watching TV, namely the loudness of different channels varying significantly. According to an exemplary embodiment of the invention, a specific type of content, for example speech dialog, may be used as a reference for loudness, and equalizing the loudness of this type of content for all channels may be performed. This may be done by tracking and storing the long-term average loudness level of typical segments of the reference type of content for each channel. An individual gain is applied to each channel, based on the corresponding stored average level of the reference type of content, so that after some initial adaptation period, the output loudness of the reference type of content will be essentially constant across the different channels.

Therefore, it may be obtained that the same type of content, for instance speech dialog, may be automatically reproduced at the same loudness across all channels, since this will result in an overall loudness alignment of all channels, while the dynamics of the original audio signal and the different types of content are preserved.

Speech dialog may be a very suitable type of content for use as a reference, since the loudness of the speech is typically chosen such that the speech is intelligible but not too loud. Also the loudness of speech may have a direct interpretation; a whispering voice at a moderate to high loudness means that a person is close, while a shouting voice at a low loudness means that a person is far away.

According to an exemplary embodiment of the invention, audio classification may be used to identify segments of a specific class of audio (for instance speech). It is possible to use only those segments to estimate and equalize the loudness across channels, which relate to this specific class of audio. Consequently, a fully automatic (i.e. no user action is required) and very robust system may be provided in which it may be dispensable that a user specifies a reference channel. According to an exemplary embodiment of the invention, the loudness is estimated by discriminating between different content types. For this purpose, different segments of a specific class of audio may be identified.

Upon switching from the current channel to another one, the current long-term average value may be stored, and may be recalled the next time the user switches back to the channel, after which the averaging process continues, starting from the stored value. This may be advantageous, since it may ensure that after some time it is possible to reach a stable state where the stored values are really representative of the average speech loudness in each channel. Therefore, it may be possible to systematically remove relative loudness differences between channels, independent from an absolute volume setting of a television. No action of the user is required (although optionally, user-definition of the operation may be enabled), since the loudness differences that are determined and removed are inherent characteristics of the different channels. The system may therefore be fully automatic, and no user preference has to be involved.

Furthermore, it is possible to use a speech classifier to identify speech segments in the audio signal, and the loudness equalization of channels relative to each other may be based on loudness measurements of the speech segments only. In other words, the speech may be used as a reference type of content in the system according to an exemplary embodiment of the invention, and is possible to gain offsets to the individual channels such that the loudness of speech is equal for all channels. The gain offset of a channel may be applied instantaneously upon switching to the channel, before any sound has been output for the channel, so that the user does not notice any gain change.

According to an exemplary embodiment, it is possible to store the gain offset for the current channel when switching to the next channel, instantaneously recalling and applying the gain offset for that next channel from memory, and continuing the averaging process for that next channel starting from the recalled value, so that after some time (in the range of weeks/days/hours/minutes and less) the gain offsets for all channels may converge towards a stable value.

According to an exemplary embodiment, it is possible to store the “cumulative average” speech loudness of a first channel when switching to another channel. Afterwards, it is possible to recall the stored value from a memory the next time of switching to the first channel. The averaging process may be resumed from that moment until the next switch to another channel has occurred. A gain correction may be applied instantaneously at the moment of switching (or actually already before the actual switch is made), i.e. without the user noticing it. Therefore, it is possible to accumulate data whenever a channel is being watched and applying a gain offset based on that accumulated data at the moment of switching to that channel.

When a channel is activated, prior to starting the sound output for the channel, the stored average loudness value of that channel may be recalled and compared to a reference loudness value, which is the same for all channels. The gain correction is applied to the audio signal of the channel, which compensates the difference between the recalled average loudness value of the channel and the reference value. The gain correction may be applied to the point in the signal chain after a loudness estimator, otherwise it may happen that the average loudness of the process signal does not converge properly to the reference loudness value.

According to a further embodiment, it is possible to further improve the system by cross-linking it to a meta-data system such as teletext. For example, a TV program such as “Friends” should be equally loud on the various channels, so it may be possible to get further improved accuracy. In addition, several gains may be determined and stored for different shows as well even on the same channel.

Next, further exemplary embodiments of the device will be explained. However, these embodiments also apply to the multi channel audio playback apparatus, to the method, to the program element and to the computer-readable medium.

The reference audio class may be speech, particularly pure speech. Speech may be a very meaningful class of audio data for an average loudness of an audio content channel, which may result in a fast generation of reliable average values.

The audio property may comprise a loudness, a frequency spectrum, a dynamic range, or a spatial audio property. It is possible to equilibrate one or a plurality of these or other audio properties.

The averaging unit may be adapted for estimating the long-term average of the audio property of the channel by (continuously) updating a previously estimated average value for the channel with the extracted audio property of the identified segments. In other words, in each period during which a user has activated a channel, the averaging procedure may be carried out in the background. Therefore, a proper time averaged equilibration of the audio parameter may be obtained.

The device may further comprise a (for instance gain) correction unit adapted for correcting the audio property of the channel based on a comparison of the long-term average of the audio property of the channel with a reference value of the audio property. The reference value may be the value of the audio property averaged over some or all channels. Alternatively, the reference value may be fixed or may be defined by a user so as to be in accordance with user preferences.

The gain correction unit may be adapted for correcting the audio property of the channel upon activation of the channel for audio playback, particularly before starting audio playback of the activated channel. Therefore, a user will not recognize that a gain correction has been applied for adjusting loudness or any other audio parameter for the new channel, rendering the system user-friendly.

The device may further comprise a reliability estimation unit adapted for estimating a reliability parameter indicative of a statistical reliability of the estimated long-term average of the audio property of the channel. For instance, after having purchased a television device, the use time is small and the system may not have reached a stable equilibrium yet. Having a parameter indicative of the reliability may allow to avoid disturbing artefacts resulting from a system, which is not yet in the equilibrium.

The (gain) correction unit may be adapted for correcting the audio property of the channel to an extent/amount depending on the estimated reliability parameter. For instance, the gain correction unit may correct the audio property of the channel according to a first extent (which may be dependent on the exact value of the reliability parameter) when the estimated reliability parameter is below a threshold value (which can be user-defined or fixed) and may be adapted for correcting the audio property of the channel according to a second extent when the estimated/actual reliability parameter has reached the threshold value. The second extent may be a constant value and may be larger than the first extent. Therefore, the amount of reliability may have an influence on the amount of correction. The smaller the reliability, the smaller the correction to be performed.

The gain correction unit may be adapted for adjusting the threshold value depending on the estimated reliability parameter. Therefore, the threshold value may be continuously increased (or decreased), making the system self-adaptive.

The averaging unit may be adapted for estimating the long-term average of the audio property of the channel by weighting contributions of the extracted audio property of the identified segments in a time-dependent manner. For instance, very recently extracted audio property values may be weighted with a higher or smaller weighting factor than very early estimated audio property contributions.

The identification unit may be adapted for identifying segments of the audio data related to a plurality of channels simultaneously. It is possible that the system runs in the background independently of a user switching between different channels. According to such an embodiment, it is possible that the system continuously monitors the various channels, or performs such a monitoring according to a multiplexing scheme. This may allow to have a better average value even for channels, which are not activated very often.

The identification unit may be adapted for identifying segments of the audio data related to only a part of sub-channels of the selected one of the channels. For example, the playback device may be a 5.1 audio system having six loudspeakers. In such an embodiment, it may happen that only one of the loudspeakers contributes significantly to the speech. Therefore, it is sufficient to use this one sub-channel (or a part of the sub-channels) for gain estimation which may reduce the processing effort and which may increase the meaningfulness of the results.

The identification unit may be adapted for identifying segments of the audio data in each time interval between activation and deactivation of a channel. Particularly, when a user switches to a particular television channel, the identification routine may be started. When the user switches to another television channel, the identification routine may be terminated regarding the previous channel, and may then start a new identification routine regarding the new channel.

The communication between audio processing components of the audio device and reproduction units may be carried out in a wired manner (for instance using a cable) or in a wireless manner (for instance via a WLAN, infrared communication or Bluetooth).

The audio device may be a realized as a gaming device, a laptop, a portable audio player, a DVD player, a CD player, a based-based media player, an internet radio device, a public entertainment device, an MP3 player, a hi-fi system, a vehicle entertainment device, a car entertainment device, a portable video player, a medical communication system, a body-worn device, an audio conference system, a video conference system, or a hearing aid device, or any other electronic device capable of receiving audio from more than one source channel. A “car entertainment device” may be a hi-fi system for an automobile.

However, although the system according to embodiments of the invention primarily intends to facilitate the playback of sound or audio data, it is also possible to apply the system for a combination of audio data and visual data. For instance, an embodiment of the invention may be implemented in audiovisual applications like a video player in which a loudspeaker is used, or a home cinema system.

The aspects defined above and further aspects of the invention are apparent from the examples of embodiment to be described hereinafter and are explained with reference to these examples of embodiment.

### BRIEF DESCRIPTION OF THE DRAWINGS

The invention will be described in more detail hereinafter with reference to examples of embodiment but to which the invention is not limited.

FIG. 1 shows an audio data processing system according to an exemplary embodiment of the invention.

### DESCRIPTION OF EMBODIMENTS

The illustration in the drawing is schematically.

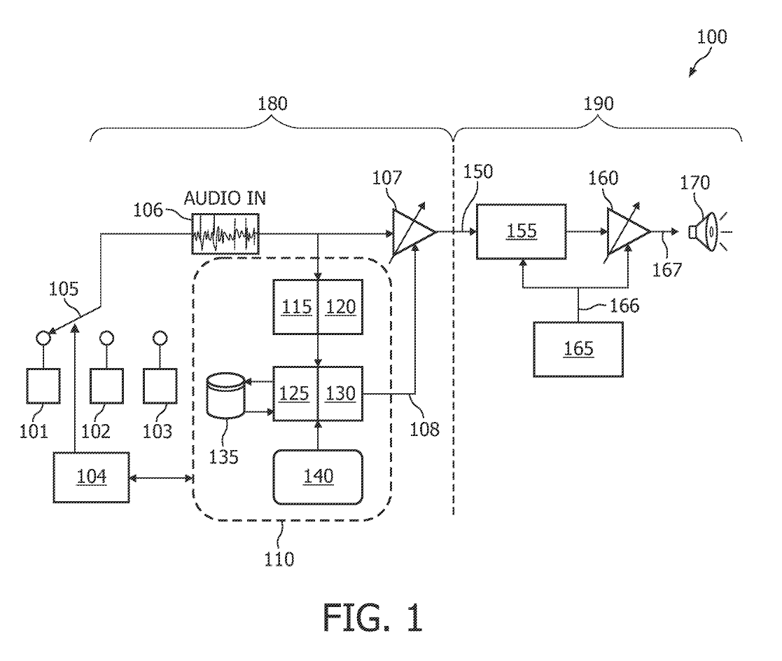

In the following, referring to FIG. 1, a television device 100 according to an exemplary embodiment of the invention will be explained.

The television device 100 allows a user to select between a first broadcasting channel 101, a second broadcasting channel 102 and a third broadcasting channel 103. A user interface 104 such as a remote control unit may allow the user to operate a switch 105 to select one of the different channels 101 to 103.

In the scenario shown in FIG. 1, the first channel 101 is selected. In accordance with a content stream provided by the first channel 101, audio data 106 is to be reproduced. This audio data 106 is sent to an adjustable amplifier 107 for amplifying an amplitude of the audio data 106 for subsequent play back.

The amplification control signal 108 defines an amplitude amplification and is generated by a device 110 for processing the audio data 106 in the multi channel audio playback apparatus 100.

The device 110 comprises an identification unit 115 adapted for identifying segments of the audio data 106 related to a selected one of the channels 101, 102, 103 and belonging to a reference audio class. More particularly, the identification unit 115 identifies speech segments within the audio signal 106 and selects these speech segments for further analysis.

An extraction unit 120 is provided which extracts a loudness value of the identified speech segments. This can be done based on an analysis of the audio amplitude or intensity in the selected speech segments.

An averaging unit 125 estimates a long-term arithmetic average of the loudness of the first channel 101 based on the extracted loudness of the identified speech segments. It is provided with the loudness values of the speech segments of the audio signal 106 and correspondingly updates a previously stored long-term average of the loudness of the channel 101 in a database 135.

This long-term arithmetic average information may be supplied to a gain correction unit 130. The gain correction unit 130 generates the control signal 108. The regulator unit 130 compares the long-term average with a reference value stored in a reference unit 140 (which may be a memory), and on the basis of this measurement sets the control signal 108 for performing a gain correction of the audio signal 106.

The correspondingly modified audio signal 150 is then supplied to a compressor unit 155 and from there to a second adjustable amplifier 160. A master volume unit 165 generates control signals 166 for controlling the compressor 155 and the second adjustable amplifier 160 for supplying output data 167 via a loudspeaker 170 generating acoustic waves indicative of the correspondingly amplified audio data 167.

The system 100 comprises a first section 180 operating with a time constant in the order of magnitude of minutes and a second section 190 operating with a time constant in the order of magnitude of milliseconds.

The long-term process shown in the first section 180 in FIG. 1 measures the speech level of the input signal 106 using the speech loudness measurement of units 115, 120, which first identify a speech segment before performing an objective loudness measurement. The regulator 130 returns a gain output to compensate the differences between the measured speech level and a reference value stored in the reference unit 140. To prevent the user perceiving a change on volume, the adaptation may occur during the initiation of the channel. Upon switching between a channel/source 101 to 103, the last average value is stored in the memory 135 and is recalled when the channel/source 101 to 103 is reselected.

A short-term process in the second section 190 in FIG. 1 applies compression to the input signal in order to suppress any short bursts of loudness.

Upon switching to a certain channel 101 to 103, a value representative of the average loudness level of speech dialog segments in this channel 101 is read from a memory 135 by the regulator block 130. This average speech loudness value is compared to a reference loudness level stored in a reference unit 140, which is the desired loudness level of the speech dialog (relative to 0 dB, corresponding to the maximum loudness, i.e. 0 dBfs in a digital system), which is a constant and the same for all channels 101 to 103. This reference value of the reference unit 140 may be set to the same reference dialog loudness level used in the broadcasting industry. By comparing the stored averaged speech loudness level of the selected channel 101 and the reference loudness level, a gain factor is computed by the unit 130, which normalizes the speech loudness level of the selected channel 101 to the reference value. This gain is applied to the input audio signal 106 of the selected channel 101 prior to the moment that the channel's audio signal 106 is connected to the audio output unit 170, so the user does not notice the gain change.

From the moment that the switch 105 has been operated, the incoming audio signal 106 is continuously analyzed by the speech loudness measurement block 115, 120 which has two functions: First, it identifies sections in the incoming audio signal that contain pure speech, i.e. speech without background noise, music, etc. Secondly, it measures the loudness level of the identified speech segments. This may be implemented for example as a simple root mean square signal level measurement algorithm.

The measured loudness value of the current speech signal may be used by the regulator block 130, 125 to update the average speech loudness value for this channel 101. This way, at any moment the average loudness level value represents the average loudness level for all speech dialog segments that have been analyzed for this channel since the first time this channel was analyzed (typically the first time the channel was selected after purchasing the TV). Finally, upon switching to a different channel, the updated average speech loudness value of a current channel 101 is written to the memory 135 and may be recalled the next time that the user switches to the channel 101, to adapt the gain.

This way, after some initial adaptation time period, a stable average of the speech loudness level of each channel 101 to 103 will be reached and the loudness of each channel 101 to 103 can be normalized to the reference loudness level automatically.

Optionally, the device 110 may comprise a reliability estimation unit 143 adapted for estimating a reliability parameter indicative of a statistical reliability of the estimated long-term average of the audio property of the channel 101. The reliability estimation unit 143 may receive information regarding the long-term average from the database 135 and may forward corresponding reliability data to the regulator block 130 for consideration when generating the control signal 108.

Generally speaking, a speech classification algorithm may analyze an audio signal and output the probability that the signal should be classified a speech. This means that there may be a certain amount of uncertainty involved in the identification process, and a probability threshold needs to be selected for deciding whether a segment is treated as speech or not. If the threshold is chosen very low, then it is possible to recognize almost all true speech segment as speech, with the risk of also incorrectly identifying segments as speech that do not consist of pure speech. This would result in an incorrect estimate of the average speech loudness level. On the other hand, if the threshold is set to a high value, the risk is reduced of incorrectly identifying segments as speech, with a trade-off of not recognizing some true speech segments as speech, which in the present application means a relatively slow adaptation of the average speech loudness level value to the true average value. However, it may be desired to obtain a reliable average speech level estimate, rather than quick adaptation. Therefore, the threshold may be typically chosen high enough to ensure that there are very few incorrect speech identifications, such that the influence on the average speech loudness level estimate can be neglected.

In the initial time period after the analysis process of a channel has started (typically the period shortly after purchasing the TV), the estimate of the average speech loudness level of each channel is based on only a limited amount of data, especially for channels that are not watched very often. This means that, even with a relatively high threshold value, the estimates are not that reliably yet. It is not desirable adapting the gain of a channel using an unreliable estimate, as this could, in a worst-case scenario, actually increase the loudness differences between channels.

To avoid that this happens, in an embodiment of the invention the amount of gain modifications is made dependent on the reliability of the estimate of the average speech loudness level. That is to say that while the reliability of the estimate of the average speech loudness level is still below a certain threshold, the calculated gain normalization factor that results from comparing the estimate of the average speech loudness level to the reference value is not fully applied, but only a certain percentage (between 0% and 100%) of it that is dependent on the reliability of the estimate. Only once a sufficient amount of data is available so that the estimate of the average reaches a certain reliability, the calculated gain normalization factor is applied fully (for instance 100%).

Setting the threshold for speech identification to a high value, which may be desirable to obtain a reliable estimate of the average speech loudness, may have the disadvantage that adaptation can be quite slow, as only the segments for which it is almost certain that they consist of pure speech are used for updating the average loudness value. This means that only after a considerable amount of time after purchasing the TV, the consumer will start to notice the benefit of the automatic loudness equalization functionality, especially for channels that are watched only occasionally.

To eliminate this problem, in an embodiment of the invention the threshold value may be made adaptive. At first, from the first use of the TV, when there is no speech loudness data available yet, the threshold may be set to a low value, so that quickly speech loudness data becomes available to start estimation of the average loudness level. The data obtained in this first period may contain segments that are not pure speech, so the reliability of the estimate is not very good yet. However, over time, as the amount of data on which the estimate of the average is based increases, the threshold is slowly increased, so that as time progresses, the reliability of the data that is used to update the estimate of the average, and therefore the estimate itself, increases. Optionally, as more (and more reliable) data becomes available, the data obtained in the initial phase may be discarded, so as to increase the reliability of the estimate even more.

This embodiment can be combined with the previous embodiment, that is to say, that while the threshold is still low (and thus also the reliability of the estimate of the average), only a certain percentage of the calculated gain normalization factor is applied, with a percentage increasing to 100% as the threshold reaches its maximum value.

According to another exemplary embodiment, only a limited amount of speech loudness level measurements from the recent past is used to estimate the average speech loudness level of a channel (for instance by either limiting the sum of the length of the segments used, starting from the most recent segment and looking back in time, or by limiting the absolute time period before the current moment that is included). This has the advantage that the system is able to adapt to possible long-term variations of the long-term average speech loudness level of each channel and, when an adaptive (increasing) threshold value is used, as described above, that after a while the estimate of the average speech loudness will only be based on highly reliable data.

In a further embodiment, the fact may be exploited that TVs may contain two or more individual tuners, to enable “picture in picture” type functionality. Rather than just analyzing the speech loudness of the channel that is currently being watched, the second tuner (and further tuners) may be exploited to perform a continuous cyclic analysis of the speech loudness level of all channels as a background process. This may have an advantage that the adaptation to a stable average speech loudness level estimate will be fast for all channels, not just for the channels that are watched often (as is the case with only a single tuner).

To increase the reliability and/or adaptation speed of the system, external information about the probability that a certain signal does or does not contain speech may be used as a sort of “pre-processor”. For example, when one of the input sources of the system contains 5.1 surround sound content (for instance a TV channel broadcasting digital surround sound program material or a DVD player connected to the home entertainment set), then almost all speech will be obtained in the center audio channel of the 5.1 signal. In such a case, it makes sense to only use the center channel to determine the average speech loudness level of this input source. In this case, the resulting gain compensation factor that is calculated may be applied locally to the 5.1 signal, not just to the center channel, as this may disturb the balance between the center channel and the other channels.

While the invention has been illustrated and described in detail in the drawings and foregoing description, such illustration and description are to be considered illustrative or exemplary and not restrictive; the invention is not limited to the disclosed embodiments.

Other variations to the disclosed embodiments can be understood and effected by those skilled in the art in practicing the claimed invention, from a study of the drawings, the disclosure, and the appended claims. In the claims, the word “comprising” does not exclude other elements or steps, and the indefinite article “a” or “an” does not exclude a plurality. A single processor or other unit may fulfill the functions of several items recited in the claims. The mere fact that certain measures are recited in mutually different dependent claims does not indicate that a combination of these measured cannot be used to advantage. A computer program may be stored/distributed on a suitable medium, such as an optical storage medium or a solid-state medium supplied together with or as part of other hardware, but may also be distributed in other forms, such as via the Internet or other wired or wireless telecommunication systems. Any reference signs in the claims should not be construed as limiting the scope. It should also be noted that reference signs in the claims shall not be construed as limiting the scope of the claims.

1. A device (110) for processing audio data (106) for a multi channel audio playback system (100), the device (110) comprising
an identification unit (115) adapted for identifying segments of the audio data (106) related to a selected one of the channels (101 to 103) and belonging to a reference audio class;
an extraction unit (120) adapted for extracting an audio property of the identified segments;
an averaging unit (125) adapted for estimating an average value over a predetermined time period of the audio property of the channel (101) based on the extracted audio property of the identified segments.

2. The device (110) according to claim 1,
wherein the reference audio class is speech audio content.

3. The device (110) according to claim 1,
wherein the audio property comprises at least one of the group consisting of a loudness, a frequency distribution, a dynamic range, and a spatial audio property.

4. The device (110) according to claim 1,
wherein the predetermined time period is a time period during which the channel is selected.

5. The device (110) according to claim 1,
wherein the predetermined time period covers two or more time periods during which the channel is selected.

6. The device (110) according to claim 1,
wherein the estimating is also based on a previously estimated average value for the channel (101).

7. The device (110) according to claim 1,
comprising a correction unit (130) adapted for correcting the audio property of the channel (101) based on a comparison of the average value of the audio property of the channel (101) with a reference value of the audio property.

8. The device (110) according to claim 7,
wherein the reference value of the audio property is one of the group consisting of a value of the audio property averaged over the channels (101 to 103), a user-defined value, and a predetermined value.

9. The device (110) according to claim 8,
wherein the correction unit (130) is adapted for correcting the audio property of the channel (101) upon activation of the channel (101) for audio playback, particularly before starting audio playback of the activated channel (101).

10. The device (110) according to claim 1,
comprising a reliability estimation unit (143) adapted for estimating a reliability parameter indicative of a statistical reliability of the estimated average value of the audio property of the channel (101).

11. The device (110) according to claim 7,
wherein the correction unit (130) is adapted for correcting the audio property of the channel (101) to a quantity, which depends on the estimated reliability parameter.

12. The device (110) according to claim 11,
wherein the correction unit (130) is adapted for correcting the audio property of the channel (101) according to a first quantity when the estimated reliability parameter is below a threshold value and is adapted for correcting the audio property of the channel (101) according to a second quantity when the estimated reliability parameter has reached the threshold value.

13. The device (110) according to claim 1,
wherein the averaging unit (125) is adapted for estimating the average value of the audio property of the channel (101) by weighting contributions of the extracted audio property of the identified segments based on a time at which the respective segment has been processed.

14. The device (110) according to claim 1,
wherein the identification unit (115) is adapted for identifying segments of the audio data (106) related to a plurality of the channels (101 to 103) simultaneously.

15. The device (110) according to claim 1,
wherein the identification unit (115) is adapted for identifying segments of the audio data (106) related to only a part of sub-channels of the selected one of the channels (101 to 103).

16. The device (110) according to claim 1,
wherein the identification unit (115) is adapted for identifying segments of the audio data (106) in each time interval between activation and deactivation of a channel (101 to 103).

17. A multi channel audio playback apparatus (100),
comprising the device (110) for processing audio data (106) of claim 1.

18. The multi channel audio playback apparatus (100) according to claim 17,
wherein the channels (101 to 103) comprise at least one of the group consisting of different television broadcasting channels, different radio broadcasting channels, and different audio channels assigned to different audio playback modules of the multi channel audio playback apparatus.

19. The multi channel audio playback apparatus (100) according to claim 18, realized as at least one of the group consisting of an audio surround system, a mobile phone, a headset, a loudspeaker, a hearing aid, a television device, a video recorder, a monitor, a gaming device, a laptop, an audio player, a DVD player, a CD player, a based-based media player, an internet radio device, a public entertainment device, an MP3 player, a hi-fi system, a vehicle entertainment device, a car entertainment device, a medical communication system, a body-worn device, a speech communication device, a home cinema system, a home theater system, an audio server, an audio client, a flat television apparatus, an ambiance creation device, a subwoofer, and a music hall system.

20. A method of processing audio data (106) for a multi channel audio system (100), the method comprising
identifying segments of the audio data (106) related to a selected one of the channels (101 to 103) and belonging to a reference audio class;
extracting an audio property of the identified segments;
estimating an average value over a predetermined time period of the audio property of the channel (101) based on the extracted audio property of the identified segments.
